(19) United States
(12) Patent Application Publication
(10) Pub. No.: US 2026/0206351 A1
(43) Pub. Date: Jul. 16, 2026

(54) LIGHT SENSING DEVICES AND METHODS OF MANUFACTURE

(71) Applicant: Taiwan Semiconductor Manufacturing Company, Ltd., Hsinchu (TW)

(72) Inventors: Kuo-Chin Huang, Yilan City (TW); Tzu-Jui Wang, Fengshan City (TW); Chen-Jong Wang, Hsin-Chu (TW); Dun-Nian Yaung, Taipei City (TW)

(21) Appl. No.: 19/171,671

(22) Filed: Apr. 7, 2025

Related U.S. Application Data
(60) Provisional application No. 63/743,670, filed on Jan. 10, 2025.

(51) Int. Cl. H10F 39/00

(52) U.S. Cl. CPC H10F 39/809; H10F 39/018; H10F 39/811

(57) ABSTRACT

A single photon avalanche diode (SPAD) image sensor including at least three device layers. The first device layer has an array of SPADs. The second device layer provides in-pixel circuitry for the SPADs. Row driver circuits, column readout circuits, and other circuits are in the third device layer or in a fourth device layer. The first device layer can be manufactured with a streamlined process that does not produce any transistors. The second device layer can be manufactured with a mature process technology that provides high voltage transistors. The third and optional fourth device layer can be manufactured with advanced process technology that provides high density transistors having lower operating voltages than are required for the in-pixel circuitry. This structure increases the number of SPAD pixels that can be provided per unit device area and is cost-effective.

### REFERENCE TO RELATED APPLICATION

This Application claims priority to U.S. Provisional Application number 63/743,670, filed on Jan. 10, 2025, the contents of which are hereby incorporated by reference in their entirety.

### BACKGROUND

A single-photon avalanche diode (SPAD) is a type of solid-state photodetector that can register single photons for image acquisition, range finding, and other applications. An SPAD includes an absorption region and a multiplication region. The multiplication region comprises a reverse biased p-n junction. Photons absorbed in the absorption region generate electron-hole pairs. The charge carriers are accelerated by the high electric field of the reverse biased p-n junction. The accelerated charge carriers cause impact ionization and an avalanche multiplication process that results in a detectable signal. In Gieger-mode, the p-n junction is reverse biased above a breakdown voltage, which makes the avalanche process self-sustaining. A quench process resets the SPAD after a detection event.

### BRIEF DESCRIPTION OF THE DRAWINGS

Aspects of the present disclosure are best understood from the following detailed description when read with the accompanying figures. In accordance with standard industry practice, features are not drawn to scale. Moreover, the dimensions of various features within individual drawings may be arbitrarily increased or reduced relative to one-another to facilitate illustration or provide emphasis.

FIG. 1 illustrates an exploded view of an integrated circuit (IC) device according to an embodiment of the present disclosure.

FIG. 2 provides a circuit diagram of an SPAD pixel circuit according to an embodiment of the present disclosure.

FIG. 3 illustrates a cross-sectional view of an IC device according to an embodiment of the present disclosure.

FIGS. 4-13 provide a series of cross-sectional views illustrating an IC device manufacturing process according to an embodiment of the present disclosure.

FIG. 14 provides a flow chart of a process according to an embodiment of the present disclosure

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

Spatially relative terms, such as “beneath,” “below,” “lower,” “above,” “upper”, and the like, may be used herein to describe one element or feature's relationship to another element(s) or feature(s) as illustrated in the figures. These spatially relative terms are intended to encompass different orientations of the device or apparatus in use or operation in addition to the orientation depicted in the figures. The device or apparatus may be otherwise oriented (rotated 90 degrees or at other orientations) and the spatially relative descriptors used herein may be interpreted accordingly. Terms “first”, “second”, “third”, “fourth”, and the like are merely generic identifiers and, as such, may be interchanged in various embodiments. For example, while an element (e.g., an opening) may be referred to as a “first” element in some embodiments, the element may be referred to as a “second” element in other embodiments.

SPAD p-n junctions are reverse biased above their breakdown voltages by high voltages (>10 V). Quench and recharge circuits, and other in-pixel circuitry for SPADs, use transistors that operate at these high voltages. These high-voltage transistors use mature semiconductor technologies that inherently have a comparatively large minimum transistor spacing. In a multi-layer device, the in-pixel circuitry can be placed in an array on a second device layer and has approximately the same footprint as that of the SPAD array in the first device layer so that each in-pixel circuit can be directly opposite its corresponding SPAD and connected thereto by short connections. Circuits that interface with the in-pixel circuits, including at least the row driver circuits and column readout circuits, are ordinarily positioned in peripheral areas adjacent the edges of the in-pixel circuit array. The peripheral circuits take up a substantial amount of space so that the SPAD in-pixel circuits and the SPAD themselves are limited to 20-25% of the total chip area.

The present disclosure solves this problem by relocating the row driver circuits, the column readout circuits, and other such circuits to a third device layer. The third device layer can operate at lower voltages than the second device layer (e.g., <2.8 V) and can therefore be manufactured with advanced process technology that provides high density transistors restricted to lower operating voltages. In some embodiments a fourth device layer is also included. The fourth device layer may provide an application-specific integrated circuit (ASIC). The reduction in area for peripheral circuitry allows more chip area to be devoted to SPADs, increasing the achievable resolution and efficiency for an SPAD-based image sensor.

Accordingly, one aspect of the present disclosure is an integrated circuit device that includes at least three device layers. The first device layer includes a semiconductor substrate with an array of SPADs. In some embodiments, this layer is dedicated to photon detection and does not include any transistors, allowing the SPADs to be fabricated using a streamlined process adapted to providing SPADs that are highly sensitive and efficient.

The second device layer, which is bonded to the first device layer at a pixel level, contains in-pixel circuits including at least quench and recharge circuits for the SPADs. Since these in-pixel circuits operate at high voltages, this layer is fabricated using a semiconductor process suitable for high-voltage transistors, which dictates relatively large transistor spacings. This can be a mature technology that offers high reliability and low cost.

A third device layer is bonded to the second device layer. This third device layer includes row driver circuits, column readout circuits, and potentially other circuits that provide logic or control functions. Because these circuits do not need to operate at high-voltages, they can be fabricated using a more advanced semiconductor technology with smaller transistor spacings, enabling higher circuit density and a reduced footprint for those circuits. Electrical connections between the second and third device layers are facilitated by row and column connectors on the second device layer and by through-silicon vias (TSVs) extending through the second device layer. In some embodiments, the row driver circuits and column readout circuits occupy the same area they would if on the second device layer, which is outside the footprint of the SPAD and in-pixel circuit arrays. This positioning maintains short connection lengths and allows efficiency comparable to that which would be realized if these circuits were located on the second device layer.

In some embodiments, additional functionality is integrated into the third device layer. In some embodiments, this additional functionality includes clock management circuits such as a phase-locked loop (PLL) and a delay-locked loop (DLL). In some embodiments, this additional functionality includes an image signal processor (ISP). The PLL, the DLL, and the ISP circuits may be positioned in the footprint of the SPAD array. In some embodiments, the integrated circuit device includes a fourth device layer. The fourth device layer may include an application-specific integrated circuit (ASIC) that provides higher-level processing and interfacing functions. The first three device layers may be limited to image sensing functionality whereas the ASIC may provide other functionality that leverages the image sensing functionality.

Another aspect of the present disclosure is a method for manufacturing the integrated circuit device. This method includes forming and bonding the three (or more) device layers in a manner that ensures reliable electrical connectivity while allowing each layer to be fabricated using a semiconductor process optimized for its specific function. The method enables efficient integration of SPAD arrays with high-voltage circuits while allowing logic and control to be implemented with high density low-voltage circuits so that area available for photon detection is increased.

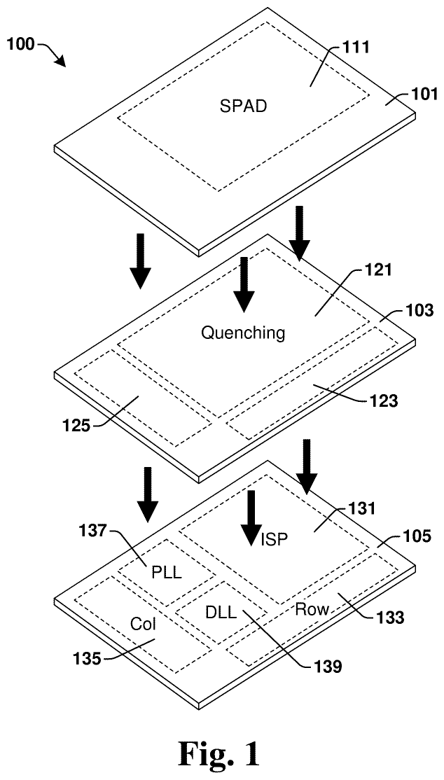

FIG. 1 illustrates an exploded view of an integrated circuit device 100 in accordance with some embodiments. The integrated circuit device 100 includes a first device layer 101, a second device layer 103, and a third device layer 105 which are bonded together. The first device layer 101 includes an SPAD array 111. In some embodiments, the SPAD array 111 includes from about 32 ×32 to about 320×232 pixels (individual SPADs). In some embodiments, the SPAD array 111 includes more than 320×232 pixels. In some embodiments, the SPAD array includes over a million pixels. Larger numbers of pixels provide greater resolution. The present disclosure provides structures that enable larger numbers of pixels to be provided on a chip of given size.

The SPADs in the SPAD array 111 include an absorption region provided by a light-sensitive semiconductor. The absorption region may be part of a semiconductor substrate, embedded in the semiconductor substrate, or in the form of a mesa on the semiconductor substrate. The absorption region can be any suitable semiconductor and is selected according to a wavelength of light to be detected.

In some embodiments, the absorption region is silicon or the like. Silicon absorbs visible to near-infrared light, i.e., from about 300 nm to about 1100 nm, and is suitable for both direct time-of-flight (dToF) and photon-counting image sensors. Silicon SPADs may be produced with CMOS-compatible processing. Applications for silicon SPADs include light detection and ranging (LiDAR) and 3D imaging systems. Silicon p-n junctions have a reverse breakdown in the range from about 20 V to about 200 V. A suitable bias voltage for an SPAD is the reverse breakdown plus an excess bias voltage. For a silicon SPAD, the excess bias voltage is from about 2 V to about 10V. If the excess bias voltage is too low, photon detection efficiency will be compromised. If the excess bias voltage is too large, dark currents can be excessive.

In some embodiments, the absorption region is germanium or the like. Germanium absorbs near-and mid-infrared light, i.e., from about 800 nm to about 1500 nm, and is suitable for dToF and other LIDAR systems. Applications for germanium SPADs include long-range LiDAR and telecommunication systems. In some embodiments, the germanium SPAD is germanium on silicon. In some embodiments, the germanium on silicon SPAD comprises a heterojunction diode. For germanium p-n junctions, the reverse breakdown voltage is from about 5 V to about 30 V and the excess bias voltage is from about 1 V to about 3 V. For germanium on silicon SPADS, the reverse breakdown voltage is from about 10 V to about 50 V and the excess bias voltage is from about 2 V to about 5 V.

In some embodiments, the absorption region is indium gallium arsenide (InGaAs) on indium phosphide (InP) or the like. Indium gallium arsenide absorbs wavelengths in the range from about 1000 nm to about 1700 nm and is suitable for dToF and photon-counting systems. Applications include LiDAR, telecommunication, and imaging systems. The integrated circuit device 100 is illustrated as a dToF system but can readily be adapted to any of these applications. For InGaAs on InP SPADs, the reverse breakdown voltage is from about 10 V to about 50 V and the excess bias voltage is from about 2 V to about 6 V.

The second device layer 103 includes an in-pixel circuit array 121. The in-pixel circuit array 121 has in-pixel circuits in one-to-one correspondence with the SPADs in the SPAD array 111. There is at least one electrical connection between the first device layer 101 and the second device layer 103 for each pixel. In some embodiments, the in-pixel circuit array 121 is within the footprint of the SPAD array 111 to within a single pixel's width. Row connectors 123 and column connectors 125 are disposed laterally to the in-pixel circuit array 121 and are coupled thereto through row busses and column busses (not shown). The in-pixel circuits include quench and recharge circuits, and circuitry for producing a digital or other low voltage output from SPAD avalanche events.

The third device layer 105 includes row driver circuits 133 and column readout circuits 135. In some embodiments, the third device layer 105 further includes one or more of a phase-locked loop (PLL) 137, a delay-locked loop (DLL) 139, and an image signal processor (ISP) 131. In some embodiments, the row driver circuits 133 and the column readout circuits 135 are underneath the row connectors 123 and the column connectors 125 outside the footprint of the SPAD array 111. In some embodiments, the PLL 137, the DLL 139, and the ISP are within the footprint of the SPAD array 111. This configuration limits connection lengths between the row driver circuits 133, the column readout circuits 135, and the circuits of the in-pixel circuit array 121 while making efficient use of area in the third device layer 105.

This in-pixel circuitry includes at least a quench and recharge circuit, which is responsible for stopping an avalanche event in the SPAD after photon detection and ensuring the diode is properly recharged for subsequent detections, and a signal processing circuit that provides a low voltage output signal in response to the avalanche event. The quench and recharge circuit can be a passive quench and recharge circuit, where a high-value resistor is used to limit current flow and restore the SPAD to its operating bias. Alternatively, a quench and recharge circuit can be an active quench and recharge circuit, which includes a feedback-controlled transistor that rapidly pulls down the SPAD voltage to stop the avalanche with greater speed and control compared to passive quenching.

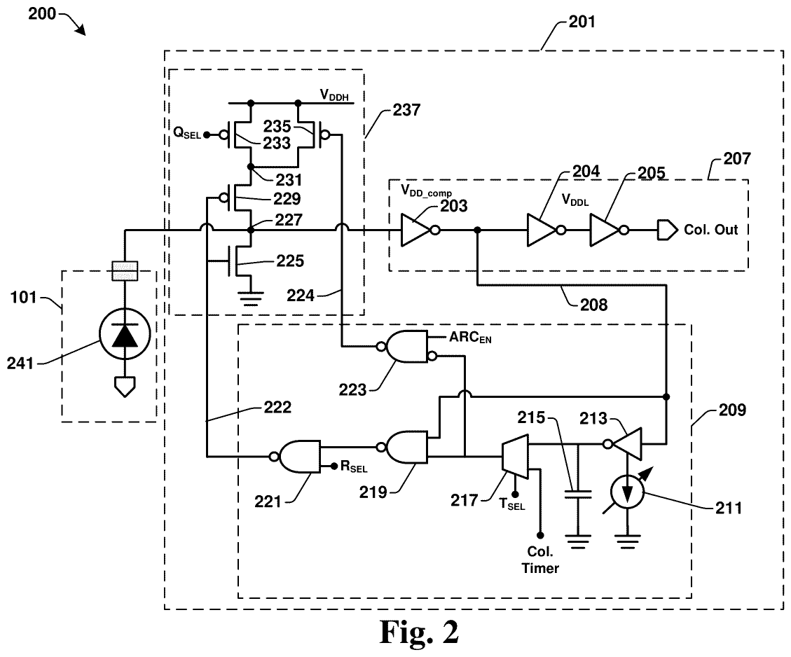

FIG. 2 provides a circuit diagram 200 illustrating an SPAD 241 and its in-pixel circuitry 201. The SPAD 241 is in the first device layer 101. The in-pixel circuitry 201 is in the second device layer 103 (see FIG. 1) and provides an active quench and recharge circuit. In particular, the in-pixel circuitry 201 includes a quench and recharge circuit 237, a signal processing and output circuit 207, and a timing and control circuit 209.

The signal processing and output circuit 207 converts transient analog avalanche events into low voltage (logic-level) output signals. The circuit includes first, second, and third inverters 203, 204, and 205 in series. The first inverter 203 is a comparator powered by V_{DD_comp}. The first inverter 203 converts avalanche pulses from the SPAD 241 into logic-level signals. The second and third inverters 204 and 205 are a buffer and driver that condition (amplify and shape) the logic-level signal to produce a clean digital pulse at V_{DDL} that is passed to a column bus which is shared by a first plurality of SPADs 241. V_{DDL} is the operating voltage of the third device layer 105 (see FIG. 1), and is less than V_{DDH}, the operating voltage of the second device layer 103.

The timing and control circuit 209 generates control signals that drive the quench and recharge circuit 237. It can interface with timing measurements (e.g., a time-to-digital converter or external timing lines), or select between internal/external timing signals. The timing and control circuit 209 can include a fourth inverter 213, a capacitor 215, a multiplexor 217, and first, second, and third NAND gates 219, 221, and 223. The fourth inverter 213 receives a tap 208 from the signal processing and output circuit 207, which provides an indication that the SPAD 241 is firing. The output of the fourth inverter 213 helps shape an internal timing signal. The capacitor 215 modulates this timing. A switch 211 may be used to reset the output of the fourth inverter 213 to rearm the timing circuitry between avalanche events.

The multiplexor 217 selects between the internal timing signal and an external timing signal (column timer) based on a time mode select (Tₛₑₗ) signal. The output of the multiplexor 217 goes through further logic so that the timing and control circuit 209 uses one or the other timing signal to control the quench and recharge circuit 237, depending on the operating mode. In particular, the third NAND gate 223 provides a recharge control signal 224 according to the timing signal and a setting for an active recharge enable (ARC_{EN}) signal. The first and second NAND gates 219 and 221 provide a quench activation signal 222 according to the timing signal, the avalanche signal from the tap 208, and a row select signal (Rₛₑₗ). The row select signal Rₛₑₗ can come from a row bus which is shared by a second plurality of SPADs 241.

The quench and recharge circuit 237 includes a floating node 227, a recharge node 231, an active quenching switch 225, a recharge switch 229, a quench bias transistor 233, and a recharge enable transistor 235. The floating node 227 is connected to a cathode of the SPAD 241. The active quenching switch 225 is an NMOS transistor connected between the floating node 227 and ground. The recharge switch 229 is a PMOS transistor connected between the floating node 227 and the recharge node 231. The active quenching switch 225 and the recharge switch 229 are both controlled by the quench activation signal 222. Together, these transistors can force the floating node 227 to ground or allow it to be driven to the voltage of the recharge node 231, depending on the quench activation signal 222.

The quench bias transistor 233 is connected between the high voltage V_{DDH} and the recharge node 231. It is regulated by a quench bias signal (Qₛₑₗ) to help extinguish avalanche events in a controlled manner. The recharge enable transistor 235 is also connected between the high voltage V_{DDH} and the recharge node 231. The recharge enable transistor 235 provides a fast recharge path controlled by recharge control signal 224.

When a photon triggers an avalanche in the SPAD 241, the voltage of the floating node 227 quickly drops (or rises, depending on the polarity). The processing and output circuit 207 detects the pulse and provides a low voltage digital output signal to the column bus. The timing and control circuit 209 detects the avalanche event and asserts the quench activation signal 222, which closes the active quenching switch 225 and lowers the voltage on the floating node 227. After a brief delay, the recharge control signal 224 goes active and the floating node 227 is restored to the reverse bias voltage.

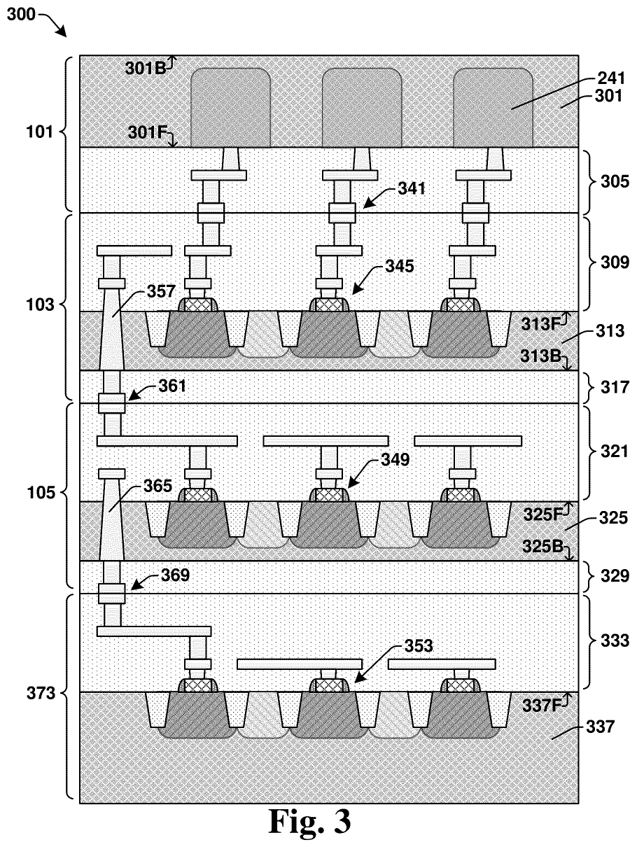

FIG. 3 illustrates a cross-sectional view of an integrated circuit device 300 in accordance with some embodiments. The integrated circuit device 300 includes the first device layer 101, the second device layer 103, the third device layer 105, and a fourth device layer 373. The fourth device layer 373 includes a plurality of semiconductor devices including transistors 353 on a front side 337F of a semiconductor substrate 337. The semiconductor devices are interconnected by a metal interconnect structure 333 and form an ASIC. The fourth device layer 373 is bonded to the third device layer 105 through a bonding structure 369.

The third device layer 105 includes a semiconductor substrate 325 having a front side 325F and a back side 325B. A plurality of semiconductor devices including transistors 349 are disposed on the front side 325F, are interconnected by a metal interconnect structure 321, and provide the PLL 137, the DLL 139, and the ISP 131 (see FIG. 1). A redistribution layer 329 is disposed on the back side 325B. TSVs 365 form connections between metal interconnect structure 321 and the redistribution layer 329. The third device layer 105 is bonded to the second device layer 103 through a bonding structure 361.

The second device layer 103 includes a semiconductor substrate 313 having a front side 313F and a back side 313B. A plurality of semiconductor devices including transistors 345 are disposed on the front side 313F, are interconnected by a metal interconnect structure 309, and provide in-pixel circuits such as quench and recharge circuits 237, signal processing and output circuits 207, and timing and control circuits 209 (see FIG. 2). The metal interconnect structure 309 also provides row buses and column buses (not shown), row connectors 123, and column connectors 125 (see FIG. 1). A redistribution layer 317 is disposed on the back side 313B. TSVs 357 form connections between row connectors 123 and column connectors 125 and the redistribution layer 317. The second device layer 103 is bonded to the second first layer 103 through a bonding structure 341.

The first device layer 101 includes a semiconductor substrate 301 having a front side 301F and a back side 301B. SPADs 241 are disposed in or on the front side 301F and are connected to the in-pixel circuitry of the second device layer 103 through a metal interconnect structure 305, which is over the front side 301F, and through the bonding structure 341. Isolations structures (not shown) provide electrical isolation between the SPADs 241. Micro-lenses, color filters, and the like may be disposed on the back side 301B.

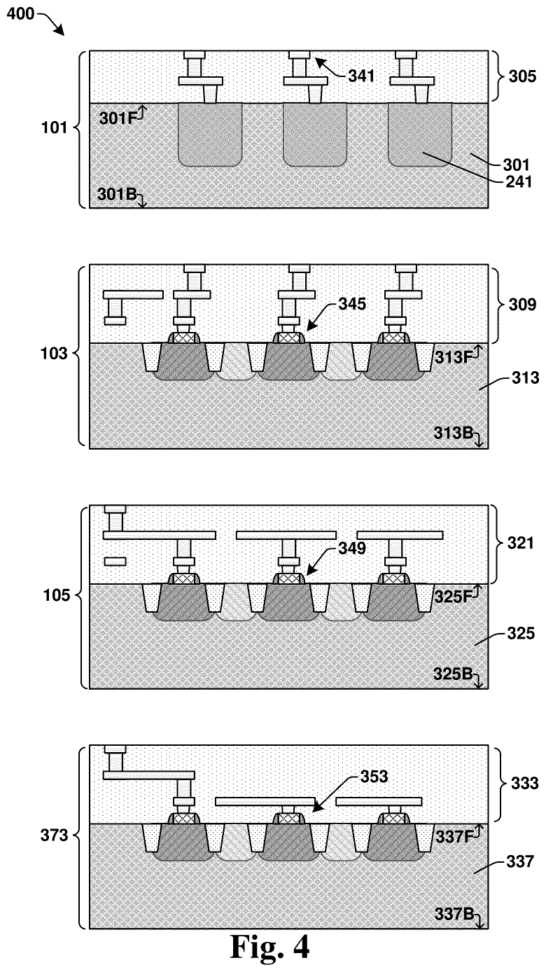

FIGS. 4-13 provide a series of cross-sectional views 400-1300 that illustrate an integrated circuit device according to the present disclosure at various stages of manufacture according to a process of the present disclosure. Although FIGS. 4-13 are described in relation to a series of acts, it will be appreciated that the order of the acts may in some cases be altered and that this series of acts are applicable to structures other than the ones illustrated. In some embodiments, some of these acts may be omitted in whole or in part. Furthermore, FIGS. 4-13 are described in relation to a series of acts, it will be appreciated that the structures shown in FIGS. 4-13 are not limited to a method of manufacture but rather may stand alone as structures separate from the method.

As illustrated by the cross-sectional view 400 of FIG. 4, the process begins with separate front-end-of-line (FEOL) and back-end-of-line (BEOL) processing of each of the first device layer 101, the second device layer 103, the third device layer 105, and the fourth device layer 373. At this stage of processing, each of these device layers may be in wafer form.

Each of the semiconductor substrates 301, 313, 325, and 337 can be a bulk semiconductor substrate or a semiconductor on insulator (SOI) substrate. At least an upper portion of each is a semiconductor. The semiconductor may be silicon (Si), a group III-V semiconductor (e.g., GaAs) or some other binary semiconductor, a tertiary semiconductor (e.g., AlGaAs), a higher order semiconductor, the like, or any other suitable semiconductor.

FEOL processing of the first device layer 101 forms the SPADs 241 in or on the semiconductor substrate 301. Forming the SPADs 241 may include doping the semiconductor substrate 301, embedding another semiconductor in the semiconductor substrate 301, or forming mesas of the other semiconductor on the semiconductor substrate 301. FEOL processing of the first device layer 101 may also include forming contact regions and isolation structures in the semiconductor substrate 301. Isolation structures may include shallow trench isolation structures, deep trench isolation structures, or doped regions potentially including a buried layer. FEOL processing of the first device layer 101 may be a specialized process sequence structure around forming the SPADs 241. In some embodiments, this specialized process sequence is characterized in part by the absence of process steps that would form polysilicon gates, metal gates, or other transistor structures on the front side 301F.

FEOL processing of the second device layer 103 forms transistors 345 and other semiconductor devices on the front side 313F of the semiconductor substrate 313. These other semiconductor devices may include diodes, capacitors, thyristors, resistors, the like, or any combination thereof. The transistors 345 are high voltage transistors capable of operating at voltages of 10 V or more. In some embodiment, the transistors 345 are capable of operating at voltages of 20 V or more. In some embodiment, the transistors 345 are planar transistors having a minimum spacing of 22 nm or greater, the minimum spacing being determined by their process of formation. In some embodiments, the transistors 345 have a minimum spacing of 28 nm or greater. In some embodiments, the transistors 345 have a minimum spacing of 40 nm or greater. In some embodiments, the transistors 345 have polysilicon gates. In some embodiments, the transistors 345 have tunnel dielectric layers that are silicon dioxide (SiO₂) or medium-k dielectrics such silicon nitride (SiN), silicon oxynitride (SiON), or the like, which have dielectric constants that are higher than that of SiO₂ but lower than 10. In some embodiments, the transistors 345 have SiO₂ tunnel dielectric layers. Planar transistors, larger transistor spacing, polysilicon gates, medium-k or SiO₂ tunnel dielectric layers are variously associated with more mature process technologies that support higher operating voltages.

FEOL processing of the third device layer 105 forms transistors 349 and other semiconductor devices on the front side 325F of the semiconductor substrate 325. These other semiconductor devices may include diodes, capacitors, memory cells, thyristors, resistors, the like, or any combination thereof. In some embodiments, the third device layer 105 includes memory cells while the second device layer 103 does not. The third device layer 105 has a maximum operating voltage of about 5 V or less. In some embodiments, the third device layer 105 has a maximum operating voltage of about 2.8 V or less.

FEOL processing of the third device layer 105 follows a different process from FEOL processing of the second device layer 103, the differences being associated with a more advanced process technology that provides higher circuit density and a lower maximum operating voltage. In some embodiments, FEOL processing of the third device layer 105 comprises lithography with shorter wavelength than are used in FEOL processing of the second device layer 103. In some embodiments, FEOL processing of the third device layer 105 uses extreme ultraviolet (EUV) lithography whereas FEOL processing of the second device layer 103 uses deep ultraviolet lithography (DUV). In some embodiments, FEOL processing of the third device layer 105 uses immersion lithography whereas FEOL processing of the second device layer 103 uses lithography in air. In some embodiments, FEOL processing of the third device layer 105 uses lithography in vacuum whereas FEOL processing of the second device layer 103 uses lithography in a non-vacuum environment. In some embodiments, FEOL processing of the third device layer 105 uses a multi-patterning process such as double patterning whereas FEOL processing of the second device layer 103 uses only single patterning.

In some embodiments, the transistors 349 of the third device layer 105 have a more technologically advanced structure from the transistors 345 of the second device layer 103. The progression of advancement is from planar transistors, to fin field-effect transistors (FinFETs), to gate-all-around (GAA) transistors, to complementary FETs (C-FETs). C-FETs are GAAs with nMOS and pMOS nanosheets vertically stacked to reduce footprint and improve performance. In some embodiments, the transistors 349 are fin-field effect transistors (FinFETs). In some embodiments, the transistors 349 are GAA transistors. In some embodiments, the transistors 349 have metal gates while the transistors 345 have non-metal gates. In some embodiments, the transistors 349 have metal gates while the transistors 345 have non-metal gates. In some embodiments, the transistors 349 have a higher-k tunnel dielectric than the transistors 345. In some embodiments, the transistors 349 have high-k dielectric tunnel dielectrics, i.e., have tunnel dielectrics with a dielectric constant of 10 or higher. Examples of high-k dielectrics include hafnium-based materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), hafnium oxide aluminum oxide (HfO₂-Al₂O₃) alloy, and the like. Additional examples of high-k dielectrics include, without limitation, zirconium oxide (ZrO₂), tantalum oxide (Ta₂O₅), aluminum oxide (Al₂O₃), yttrium oxide(Y₂O₃), lanthanum oxide (La₂O₃), strontium titanium oxide (SrTiO₃), and the like.

The transistors 349 of the third device layer 105 have a smaller minimum spacing than the transistors 345 of the second device layer 103. In some embodiments, the transistors 349 have a minimum spacing of about 22 nm or less. In some embodiments, the transistors 349 have a minimum spacing of about 12 nm or less. In some embodiments, the transistors 349 have a minimum spacing of about 7 nm or less.

FEOL processing of the fourth device layer 373 forms transistors 353 and other semiconductor devices on the front side 337F of the semiconductor substrate 337. These other semiconductor devices may include diodes, capacitors, memory cells, thyristors, resistors, the like, or any combination thereof. FEOL processing of the fourth device layer 373 may use the same process sequence as the third device layer 105 or a different process sequence, but the comparisons made between the processing used on the third device layer 105 and the processing used on second device layer 103 may also apply to comparisons between processing used on the fourth device layer 373 and the processing used on second device layer 103.

BEOL processing of the first, second, third, and fourth device layers 101, 103, 105, and 373 forms the metal interconnect structures 305, 309, 321, and 333. These metal interconnect structures include a plurality of metallization layers separated by via layers. Each metallization layer comprising conductive traces surrounded by inter-layer dielectric (ILD). Each via layer comprising conductive vias that interconnect the conductive traces and are surrounded by the ILD. The conductive traces and vias may include one or more layers of copper (Cu), tungsten (W), ruthenium (Ru), palladium (Pd), platinum (Pt), cobalt (Co), nickel (Ni), zirconium (Zi), titanium (Ti), tantalum (Ta), aluminum (Al), conductive carbides, oxides, alloys of these metals, the like, or any other suitable conductive materials. The ILD may include one or more layers of silicon dioxide (SiO₂), a low-κ interlevel dielectric, or an extremely low-κ dielectric. A low-κ dielectric is one having a smaller dielectric constant than silicon dioxide (SiO2). SiO2 has a dielectric constant of about 3.9. Examples of low-κ dielectrics include organosilicate glasses (OSG) such as carbon-doped silicon dioxide, fluorine-doped silicon dioxide (otherwise referred to as fluorinated silica glass (FSG), organic polymer low-κ dielectrics, and porous silicate glass. An extremely low-κ dielectric is a material having a dielectric constant of about 2.1 or less. An extremely low-κ dielectric material is generally a low-κ dielectric material formed into a porous structure. Porosity reduces the effective dielectric constant.

In some embodiments, the metal interconnect structures 305 of the first device layer 101 has fewer metallization layers than the metal interconnect structures 309, 321, and 333 of the second, third, and fourth device layers 103, 105, and 373. The metal interconnect structure 305 may be restricted to electrode connections for the SPADs 241 and associated isolation structures, and these connections may be primarily vertical connections to the in-pixel circuitry in the second device layers 105. The metal interconnect structures 309 of the second device layers 105 includes at least a grid of row and column buses. The metal interconnect structures 321 and 333 of the third and fourth device layers 105 and 373 provide complex electrical connections between semiconductor devices to provide the functional circuits disposed in these layers.

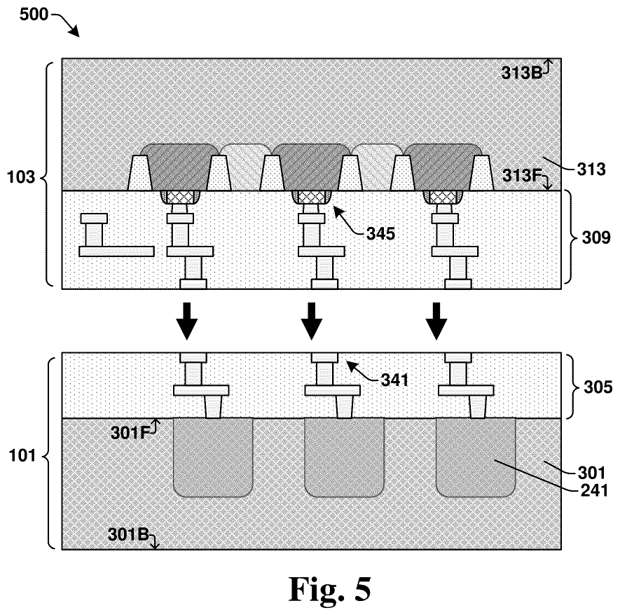

As illustrated by the cross-sectional view 500 of FIG. 5, the process continues with bonding the second device layer 103 to the first device layer 101. The bonding can be metal-to-metal bonding or a combination of metal-to-metal and dielectric-to-dielectric bonding. The bonding is pixel-level bonding in that at least one electrical connection is formed for each SPAD 241 in the SPAD array 111 (see FIG. 1).

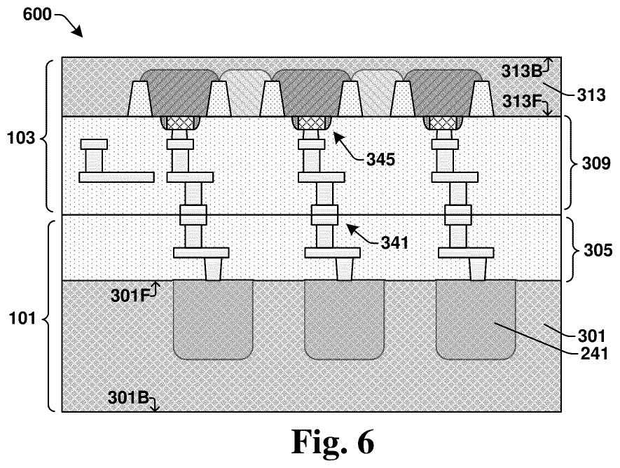

As illustrated by the cross-sectional view 600 of FIG. 6, the semiconductor substrate 313 is thinned from the back side 313B. The thinning process can include one or more of grinding, chemical mechanical polishing, plasma or wet etching, or the like. Thinning may reduce the semiconductor substrate 313 to a thickness of about 150 μm or less.

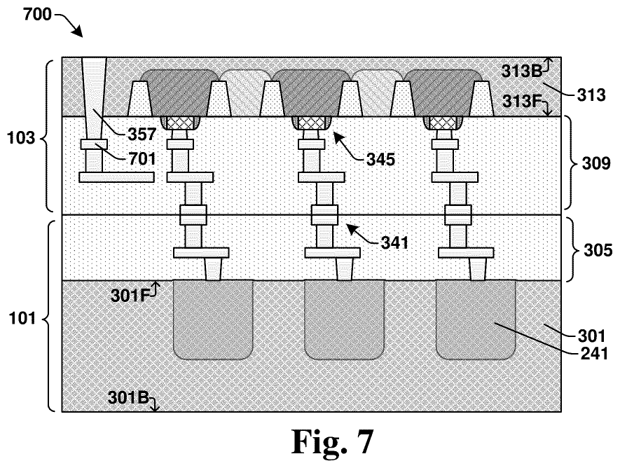

As illustrated by the cross-sectional view 700 of FIG. 7, TSVs 357 are formed through the semiconductor substrate 313. The TSVs 357 may land on conductive traces 701 in the metal interconnect structure 309. The TSVs 357 may be formed by etching holes through the semiconductor substrate 313, lining the holes with a dielectric layer, an adhesive layer, and/or a diffusion barrier layer, anisotropic etching to expose contacts such as the conductive traces 701 at the bottoms of the holes, and filling the holes with a conductive material. The conductive material may be copper (Cu), tungsten (W), aluminum (Al), polysilicon, the like, or any other suitable material.

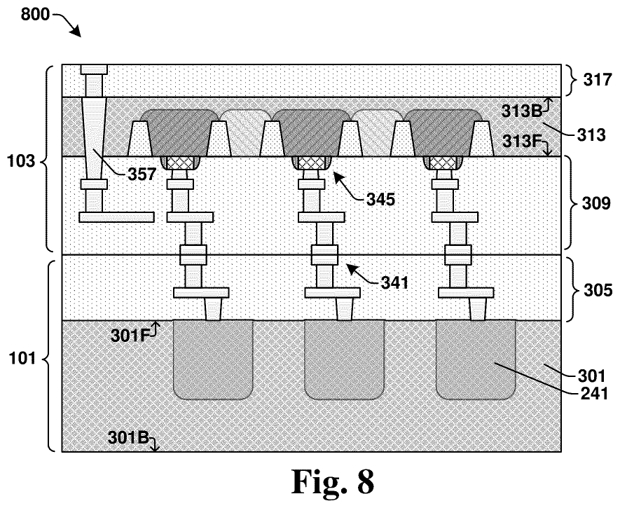

As illustrated by the cross-sectional view 800 of FIG. 8, a redistribution layer 317 may be formed on the back side 313B. The redistribution layer may comprise metallization layers, via layers, and ILD similar to one of the metal interconnect structures.

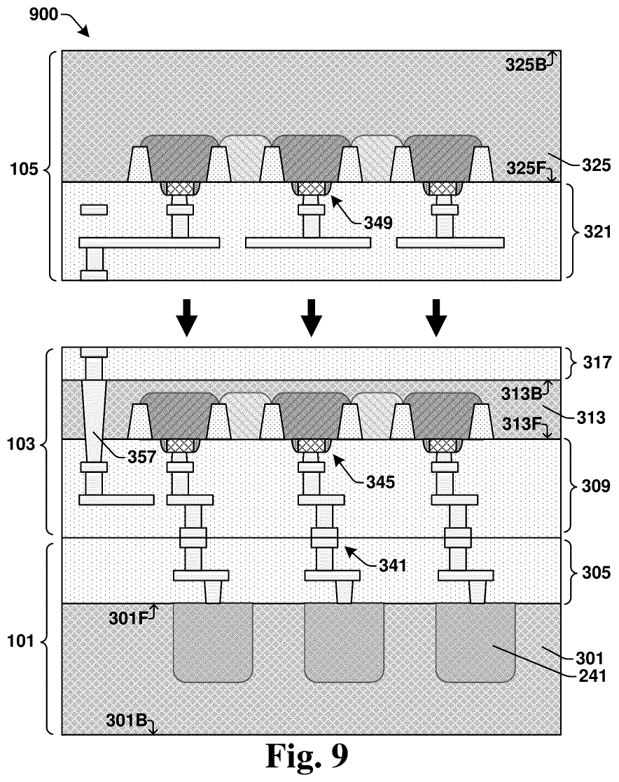

As illustrated by the cross-sectional view 900 of FIG. 9, the third device layer 105 is bonded to the second device layer 103. In some embodiments, the third device layer 105 is diced prior to bonding so that bonding involves aligning and attaching a plurality of chips to the second device layer 103. The bonding can be metal-to-metal bonding or a combination of metal-to-metal and dielectric-to-dielectric bonding.

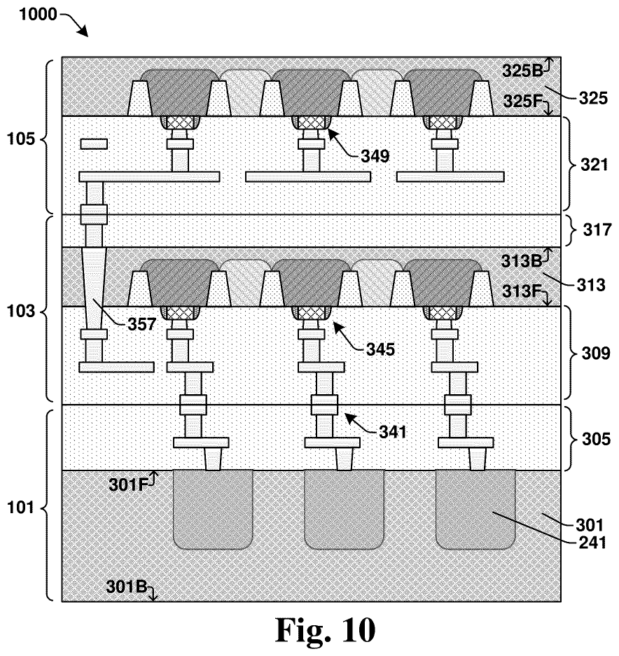

As illustrated by the cross-sectional view 1000 of FIG. 10, the semiconductor substrate 325 is thinned from the back side 325B. The thinning process can include one or more of grinding, chemical mechanical polishing, plasma or wet etching, or the like. Thinning may reduce the semiconductor substrate 325 to a thickness of about 150 μm or less.

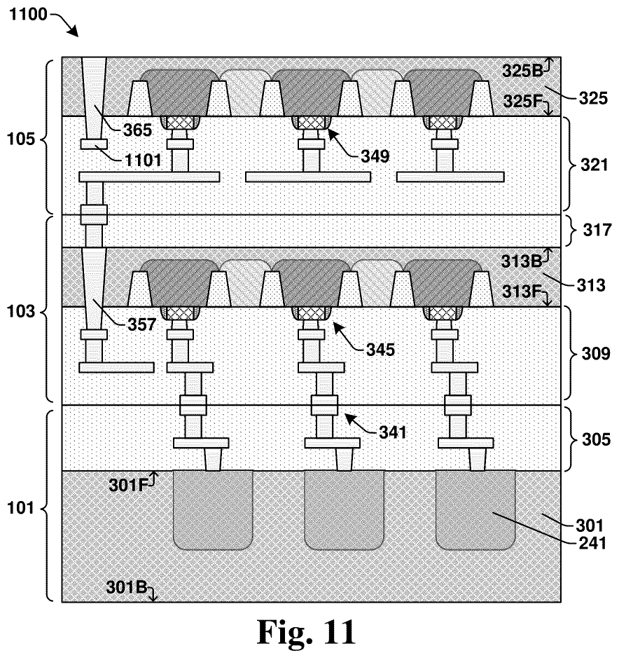

As illustrated by the cross-sectional view 1100 of FIG. 11, TSVs 365 are formed through the semiconductor substrate 325. The TSVs 365 may land on conductive traces 1101 in the metal interconnect structure 321. The composition and process of forming the TSVs 365 can be similar to the composition and process of forming the TSVs 357.

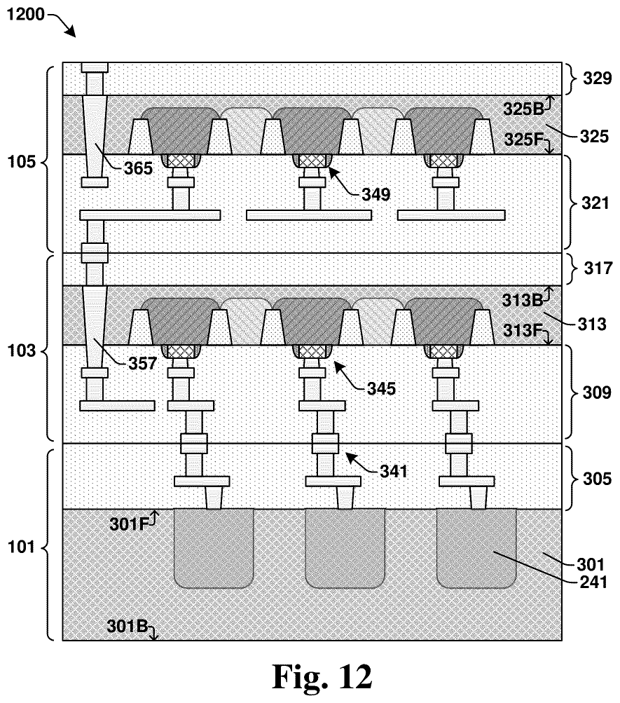

As illustrated by the cross-sectional view 1200 of FIG. 12, a redistribution layer 329 may be formed on the back side 325B. The redistribution layer may comprise metallization layers, via layers, and ILD similar to one of the metal interconnect structures.

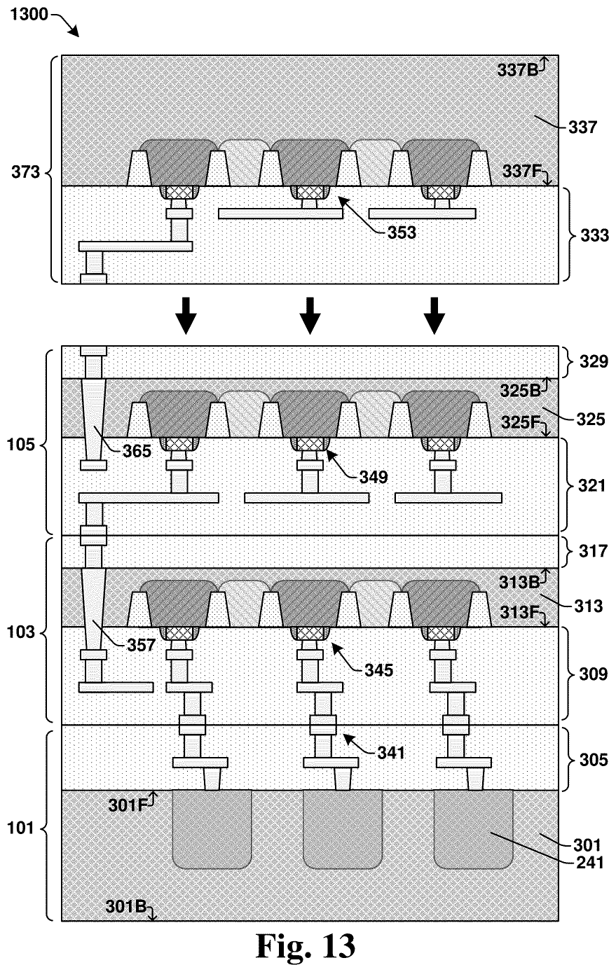

As illustrated by the cross-sectional view 1300 of FIG. 13, the fourth device layer 373 is bonded to the third device layer 105. In some embodiments, the fourth device layer 373 is diced prior to bonding so that bonding involves aligning and attaching a plurality of chips to the third device layer 105. The bonding can be metal-to-metal bonding or a combination of metal-to-metal and dielectric-to-dielectric bonding.

After the fourth device layer 373 is bonded to the third device layer 105, the semiconductor substrate 337 is thinned from the back side 337B to form the integrated circuit device 300 of FIG. 3 or a similar device. The thinning process can include one or more of grinding, chemical mechanical polishing, plasma or wet etching, or the like. Thinning may reduce the semiconductor substrate 337 to a thickness of about 50 μm or less. In some embodiments, thinning reduces the semiconductor substrate 337 to a thickness of about 10 μm or less. After thinning, additional process may take place on the back side 337B. The additional processing may form one or more of a back side deep trench isolation structure, a passivation structure, a metal grid, color filters, or micro-lenses.

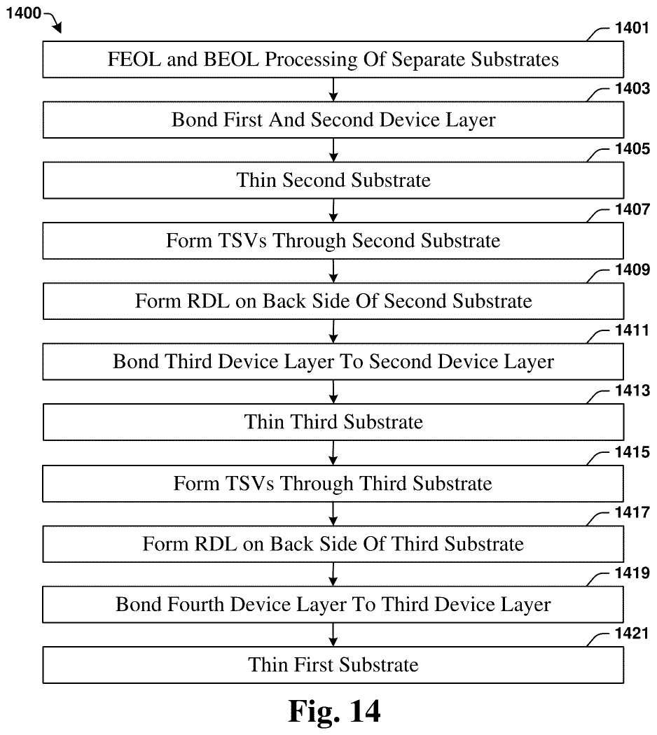

FIG. 14 provides a flow diagram for a method 1400 of forming an image sensing integrated circuit device according to some embodiments. While the method 1400 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

The method 1400 begins with act 1401, separate FEOL and BEOL processing of each of the device layers. There are three, four, or more device layers. At least the first, second, and third device layers are formed by distinct process sequences. The cross-sectional view 400 of FIG. 4 provides an example showing four device layers at the conclusion of FEOL and BEOL processing.

Act 1403 is bonding the front side of the second device layer to the front side of the first device layer. The cross-sectional view 500 of FIG. 5 provides an example.

Act 1405 is thinning the substrate of the second device layer from the back side. The cross-sectional view 600 of FIG. 6 provides an example.

Act 1407 is forming TSVs through the substrate of the second device layer. The cross-sectional view 700 of FIG. 7 provides an example.

Act 1409 is forming a redistribution layer on the back side of the second device layer. The cross-sectional view 800 of FIG. 8 provides an example.

Act 1411 is bonding the front side of the third device layer to the back side of the second device layer. The cross-sectional view 900 of FIG. 9 provides an example.

Act 1413 is thinning the substrate of the third device layer from the back side. The cross-sectional view 1000 of FIG. 10 provides an example.

Act 1415 is forming TSVs through the substrate of the third device layer. The cross-sectional view 1100 of FIG. 11 provides an example.

Act 1417 is forming a redistribution layer on the back side of the third device layer. The cross-sectional view 1200 of FIG. 12 provides an example.

Act 1419 is bonding the front side of the fourth device layer to the back side of the third device layer. The cross-sectional view 1300 of FIG. 13 provides an example.

Act 1421 is thinning the substrate of the first device layer from the back side. FIG. 3 provides an example of the resulting structure. Additional process may form micro-lenses or other on the back side of the first device layer.

Some aspects of the present disclosure relate to an integrated circuit device that includes first, second, and third device layers. The first device layer includes a first semiconductor substrate and an array of SPADs. A second device layer includes a second semiconductor substrate, is bonded to the first device layer, and includes in-pixel circuits, and row and column connectors. The in-pixel circuits include quench and recharge circuits configured to quench avalanche events in the SPADs. The third device layer includes a third semiconductor substrate, is bonded to the second device layer, and includes row driver circuits and column readout circuits configured to address the in-pixel circuits in the second device layer through the row and column connectors.

In some embodiments, the first device layer does not include any transistors. In some embodiments, the in-pixel circuits form a second array, the row and column connectors are lateral to the second array, and the row driver circuits and column readout circuits are lateral to a footprint of the second array. In some embodiments, the device further includes one or more of a phase-locked loop, a delay-locked loop, and an image signal processor on the third device layer within the footprint of the second array. In some embodiments, the device further includes a fourth device layer comprising a fourth semiconductor substrate and bonded to the third device layer. The fourth device layer includes an application-specific integrated circuit.

In some embodiments, the third device layer has a larger minimum transistor spacing than the third device layer. In some embodiments, the maximum operating voltage of the third device layer is 2.8 V or less, and the maximum operating voltage of the second device layer is 10 V or greater. In some embodiments, the third device layer has more advanced transistor structures than the second device layer. In some embodiments, the third device layer has FinFETs or GAA transistors whereas the second device layer has only planar transistors.

In some embodiments, each SPAD in the first device layer is electrically connected to a corresponding quench and recharge circuit in the second device layer by a distinct bond between the first and second device layers. In some embodiments, the row and column connectors in the second device layer are electrically coupled to the row driver circuits and the column readout circuits in the third device layer via through-silicon vias (TSVs) extending through the second semiconductor substrate. In some embodiments, in-pixel circuits each comprise a comparator configured to receive an avalanche current from a corresponding SPAD in the first device layer, the comparator being configured to generate a digitized signal in response to the avalanche current, wherein the digitized signal is at a lower voltage than the avalanche current and is provided to the third device layer.

Some aspects of the present disclosure relate to a method of manufacturing an integrated circuit device. The method includes forming a first device layer comprising a first semiconductor substrate, forming a second device layer comprising a second semiconductor substrate, and forming a third device layer comprising a third semiconductor substrate. The first device layer includes an array of single-photon avalanche diodes (SPADs). The second device layer includes in-pixel circuits corresponding to the SPADs, row and column connectors, and through-substrate vias (TSVs) corresponding to the row and column connectors. The third device layer includes row driver circuits and column readout circuits. The first device layer is bonded to the second device layer such that each SPAD in the first device layer is electrically connected to the corresponding in-pixel circuit in the second device layer by a distinct bond. The third device layer is bonded to the second device layer such that the row and column connectors in the second device layer are electrically coupled to the row driver circuits and the column readout circuits in the third device layer via the TSVs.

In some embodiments, the first device layer is formed without transistors. In some embodiments, the second device layer is formed by a process sequence that provides a minimum transistor of at least 22 nm, and the second device layer is formed by a different process sequence that provides transistors spaced less than 22 nm apart.

Some aspects of the present disclosure relate to a method of manufacturing an integrated circuit device that includes processing a first semiconductor substrate including a first front-end-of-line process that forms an SPAD array, processing a second semiconductor substrate including a second front-end-of-line process that forms an array of in-pixel circuitry including quench and recharge circuits and back-end-of-line process that forms row and column buses for the array of in-pixel circuitry, processing a third semiconductor substrate including a third front-end-of-line process that forms row driver circuits and column readout circuits, bonding the second semiconductor substrate to the first semiconductor substrate, wherein the bonding forms pixel-level electrical connections between the SPAD array and the array of in-pixel circuitry, and bonding the second semiconductor substrate to the third semiconductor substrate, wherein bonding forms electrical connections between the row driver circuits and the row busses and between the column readout circuits and the column buses.

In some embodiments, the third front-end-of-line process provides higher transistor density than second front-end-of-line process. In some embodiments, the second front-end-of-line process provides higher voltage transistors than the second front-end-of-line process. In some embodiments, the first front-end-of-line process does not form transistors. In some embodiments, the method further includes processing a fourth semiconductor substrate to form an application-specific integrated circuit and bonding the fourth semiconductor substrate to the third semiconductor substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device, comprising:
a first device layer comprising a first semiconductor substrate and an array of single-photon avalanche diodes (SPADs);
a second device layer comprising a second semiconductor substrate and bonded to the first device layer, the second device layer including in-pixel circuits comprising quench and recharge circuits configured to quench avalanche events in the SPADs, and row and column connectors; and
a third device layer comprising a third semiconductor substrate and bonded to the second device layer, the third device layer including row driver circuits and column readout circuits configured to address the in-pixel circuits in the second device layer through the row and column connectors.

2. The integrated circuit device of claim 1, wherein the first device layer does not include any transistors.

3. The integrated circuit device of claim 1, wherein:
the in-pixel circuits form a second array;
the row and column connectors are lateral to the second array; and
the row driver circuits and column readout circuits are lateral to a footprint of the second array.

4. The integrated circuit device of claim 3, further comprising one or more of a phase-locked loop, a delay-locked loop, and an image signal processor on the third device layer within the footprint of the second array.

5. The integrated circuit device of claim 1, further comprising a fourth device layer comprising a fourth semiconductor substrate and bonded to the third device layer, wherein the fourth device layer includes an application-specific integrated circuit.

6. The integrated circuit device of claim 1, wherein the third device layer has a smaller minimum transistor spacing than the second device layer.

7. The integrated circuit device of claim 1, wherein a maximum operating voltage of the third device layer is 2.8 V or less, and a maximum operating voltage of the second device layer is 10 V or greater.

8. The integrated circuit device of claim 1, wherein the third device layer has more advanced transistor structures than the second device layer.

9. The integrated circuit device of claim 1, wherein the third device layer has FinFETs or GAA transistors whereas the second device layer has only planar transistors.

10. The integrated circuit device of claim 1, wherein each SPAD in the first device layer is electrically connected to a corresponding quench and recharge circuit in the second device layer by a distinct bond between the first and second device layers.

11. The integrated circuit device of claim 1, wherein the row and column connectors in the second device layer are electrically coupled to the row driver circuits and the column readout circuits in the third device layer via through-silicon vias (TSVs) extending through the second semiconductor substrate.

12. The integrated circuit device of claim 1, wherein in-pixel circuits each comprise a comparator configured to receive an avalanche current from a corresponding SPAD in the first device layer, the comparator being configured to generate a digitized signal in response to the avalanche current, wherein the digitized signal is at a lower voltage than the avalanche current and is provided to the third device layer.

13. A method of manufacturing an integrated circuit device, comprising:
forming a first device layer comprising a first semiconductor substrate, the first device layer including an array of single-photon avalanche diodes (SPADs);
forming a second device layer comprising a second semiconductor substrate, the second device layer including:
in-pixel circuits corresponding to the SPADs and comprising quench and recharge circuits configured to quench avalanche events in the SPADs;
row and column connectors; and
through-substrate vias (TSVs) corresponding to the row and column connectors
bonding the first device layer to the second device layer, such that each SPAD in the first device layer is electrically connected to the corresponding in-pixel circuit in the second device layer by a distinct bond between the first and second device layers;
forming a third device layer comprising a third semiconductor substrate, the third device layer including row driver circuits and column readout circuits; and
bonding the third device layer to the second device layer, such that the row and column connectors in the second device layer are electrically coupled to the row driver circuits and the column readout circuits in the third device layer via the TSVs.

14. The method of claim 13, wherein the first device layer is formed without transistors.

15. The method of claim 13, wherein the second device layer is formed by a process sequence that provides a minimum transistor of at least 22 nm, and the second device layer is formed by a different process sequence that provides transistors spaced less than 22 nm apart.

16. A method of manufacturing an integrated circuit device, comprising:
processing a first semiconductor substrate, wherein the processing includes a first front-end-of-line process that forms an SPAD array;
processing a second semiconductor substrate, wherein the processing includes a second front-end-of-line process that forms an array of in-pixel circuitry including quench and recharge circuits and a back-end-of-line process that forms row and column buses for the array of in-pixel circuitry;
processing a third semiconductor substrate, wherein the processing includes a third front-end-of-line process that forms row driver circuits and column readout circuits;
bonding the second semiconductor substrate to the first semiconductor substrate, wherein the bonding forms pixel-level electrical connections between the SPAD array and the array of in-pixel circuitry; and
bonding the second semiconductor substrate to the third semiconductor substrate, wherein the bonding forms electrical connections between the row driver circuits and the row busses and between the column readout circuits and the column buses.

17. The method of claim 16, wherein the third front-end-of-line process provides higher transistor density than second front-end-of-line process.

18. The method of claim 16, wherein the second front-end-of-line process provides higher voltage transistors than the second front-end-of-line process.

19. The method of claim 16, wherein the first front-end-of-line process does not form transistors.

20. The method of claim 16, further comprising:
processing a fourth semiconductor substrate, wherein the processing forms an application-specific integrated circuit; and
bonding the fourth semiconductor substrate to the third semiconductor substrate.
